(19) United States
(12) Patent Application Publication
(10) Pub. No.: US 2024/0215140 A1
(43) Pub. Date: Jun. 27, 2024

(54) SOURCE VESSEL FOR EUV

(71) Applicant: SAMSUNG ELECTRONICS CO., LTD., Suwon-si (KR)

(72) Inventors: Daegeun Yoon, Suwon-Si (KR); Sunghyup Kim, Suwon-si (KR); Seungpyo Hong, Suwon-si (KR); Injae Lee, Suwon-si (KR)

(21) Appl. No.: 18/520,472

(22) Filed: Nov. 27, 2023

(30) Foreign Application Priority Data
Dec. 27, 2022 (KR) 10-2022-0186152

(51) Int. Cl. H05G 2/00

(52) U.S. Cl. CPC H05G 2/008

(57) ABSTRACT

A source vessel for extreme ultraviolet (EUV) includes a body that includes an outlet for discharging tin debris disposed in a central portion and an intermediate focus (IF) disposed in an upper end portion, and a reflector disposed in a lower end of the body and that includes a through-hole through which laser light passes. The body includes an IF cap portion disposed on a lower portion of the intermediate focus and that includes a heater disposed on an outer surface thereof, and an IF scanner portion disposed on an upper portion of the intermediate focus and that includes a cooling pipe disposed on an external surface thereof. An inner surface of the IF cap portion includes a flow groove through which tin residue flows, and the source vessel further includes a collection container connected to the flow groove.

### CROSS-REFERENCE TO RELATED APPLICATION(S)

This application claims priority under 35 USC 119(a) from Korean Patent Application No. 10-2022-0186152, filed on Dec. 27, 2022 in the Korean Intellectual Property Office, the contents of which are herein incorporated by reference in their entirety.

### TECHNICAL FIELD

The present inventive concept relates to a source container for extreme ultraviolet (EUV) light.

### DISCUSSION OF THE RELATED ART

When a lithography process proceeds, the inside of a source vessel that generates EUV light is filled with tin residues, and the tin residues may be externally discharged through a scrubber installed in the center of the source container.

However, after the process has been performed for a certain period of time or longer, tin debris may be generated, which cannot be discharged through the scrubber, resulting in tin debris. For example, a large amount of tin droplet debris may be observed around an Intermediate Focus (IF)-cap. Furthermore, the droplets may be eventually discharged from the source container, causing a mask defect.

### SUMMARY

Embodiments provide a source container for EUV that can prevent mask contamination.

According to embodiments, a source vessel for extreme ultraviolet (EUV) includes a body that includes an outlet for discharging tin debris disposed in a central portion and an intermediate focus (IF) disposed in an upper end portion; and a reflector disposed in a lower end of the body and that includes a through-hole through which laser light passes. The body includes an IF cap portion disposed on a lower portion of the intermediate focus that includes a heater disposed on an outer surface thereof, and an IF scanner portion disposed on an upper portion of the intermediate focus that includes a cooling pipe disposed on an external surface thereof. An inner surface of the IF cap portion includes a flow groove through which tin residue flows, and the source vessel further includes a collection container connected to the flow groove.

According to embodiments, a source vessel for EUV includes a body that includes an intermediate focus at an upper end, and a reflector disposed in a lower end portion of the body and that includes a through-hole through which laser light passes. The body includes a funnel shaped IF cap portion disposed on a lower portion of the intermediate focus that has a width that decreases toward an upper side, and a funnel shaped IF scanner portion that extends from the IF cap portion that has a width that increases toward the upper side. The IF cap portion includes a heater disposed on an outer surface and a flow groove disposed in an inner surface through which tin residue flows, and the IF scanner portion includes a cooling pipe disposed on an outer surface.

### BRIEF DESCRIPTION OF DRAWINGS

FIG. 1 illustrates extreme ultraviolet (EUV) lithography equipment in which a source container for EUV is used according to an embodiment.

FIG. 2 is an enlarged perspective view of a portion A of FIG. 1.

FIG. 3 illustrates an IF cap portion and a heater, according to an embodiment.

FIG. 4 illustrates an IF cap portion on a body of a source container for EUV, according to an embodiment.

FIG. 5 illustrates an IF cap portion on the body of a source container for EUV according to an embodiment.

### DETAILED DESCRIPTION

Hereinafter, illustrative embodiments will be described with reference to the accompanying drawings.

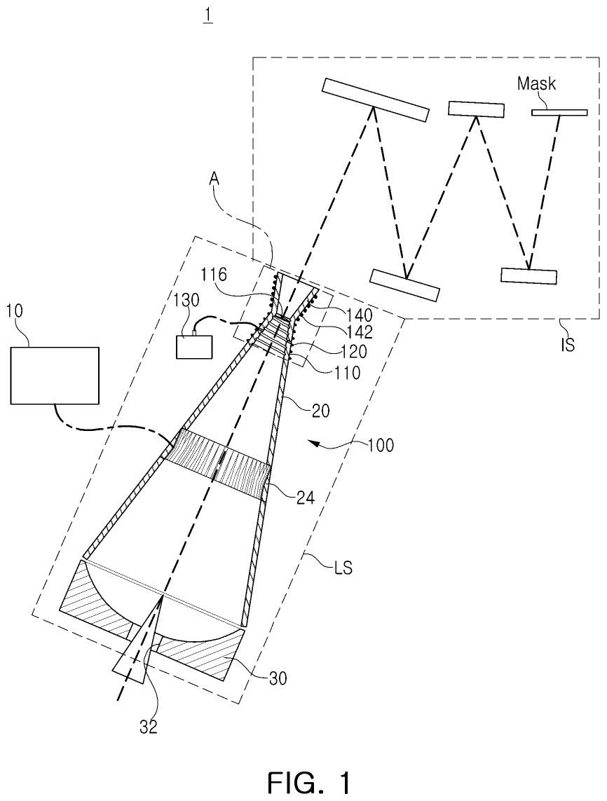

FIG. 1 illustrates extreme ultraviolet (EUV) lithography equipment in which a source container for EUV is used according to an embodiment.

Referring to FIG. 1, in an embodiment, an extreme ultraviolet ray exposure apparatus 1 includes a light source system (LS) that generates exposure light, and an optical system (IS) that adjusts and patterns the exposure light generated by the light source system (LS).

The optical system (IS) includes an illuminating optical system that transmits the exposure light generated by the light source system LS, and a mask system that patterns the exposure light transmitted from the illuminating optical system.

The light source system LS and the mask system are accommodated in a chamber that isolates the same from the outside. A vacuum pump is connected to the chamber, and a hydrogen supply device is connected to the chamber.

The light source system LS generates extreme ultraviolet exposure light by concentrating and reflecting EUV light emitted from a high temperature plasma generated by irradiating laser light with high strength pulses to a target material sprayed from a source nozzle portion onto a collector optical member.

A source container 100 for EUV is disposed in the light source system LS. The source container 100 for EUV includes a funnel-shaped body 20 in which a width of the upper end is less than a width of the lower end, and a reflector 30 coupled to the lower portion of the body 20 and that has a through-hole 32 through which laser light passes.

In addition, an outlet 24 for discharging tin residue is provided in a central portion of the body 20, and the outlet 24 is connected to a scrubber device 10 in which tin residues are introduced and treated.

The upper end portion of the body 20 is provided with an IF cap portion 110 disposed on a lower portion of an intermediate focus 116, and an IF scanner portion 140 disposed on an upper portion of the intermediate focus 116. A detailed description thereof will be given below.

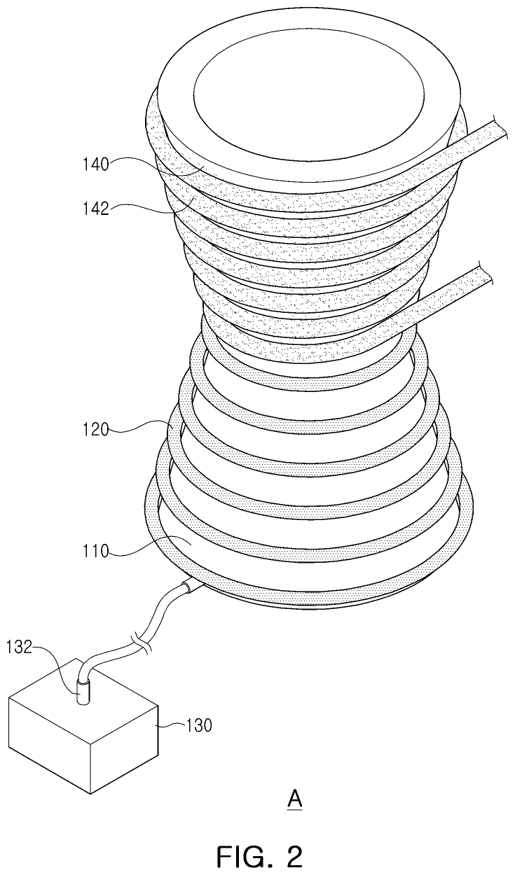

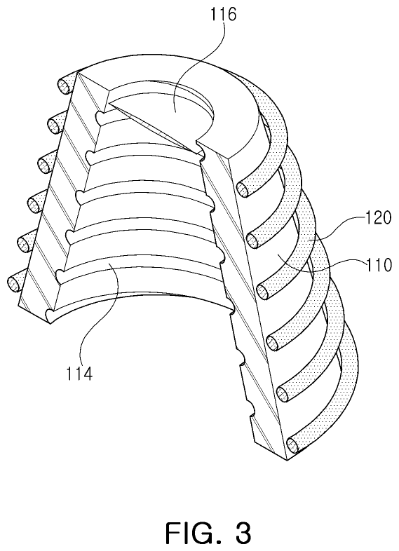

FIG. 2 is an enlarged perspective view of a portion A of FIG. 1, and FIG. 3 illustrates an IF cap portion and a heater.

Referring to FIGS. 2 and 3, in an embodiment, the IF cap portion 110 has an inner space. For example, the IF cap portion 110 has a funnel shape in which the width decreases toward the top. In addition, a flow groove 114 through which tin residue flows is provided on an inner surface of the IF cap portion 110. For example, the flow groove 114 has a spiral shape that circles around along the inner surface of the IF cap portion 110. In the flow groove 114, the tin residue heated by the heater 120 changes into a tin liquid phase, and then, serves to provide a flow path through which liquid tin flows by gravity. The intermediate focus 116 is disposed on an upper end portion of the IF cap portion 110 to provide a path through which the generated EUV light is emitted.

A heater 120 is disposed on the outer surface of the IF cap portion 110. For example, a plurality of heaters 120 are provided that are spaced apart from each other from the lower end toward the upper end of the IF cap portion 110, and the heaters have a ring shape that corresponds to the shape of the outer surface of the IF cap portion 110. The heaters 120 heat the IF cap portion 110 to prevent tin residue from solidifying on the inner surface of the IF cap portion 110. The heater 120 heats the IF cap portion 110 to maintain a temperature at or above the melting point of tin, which is 232° C. Accordingly, as the tin residue is heated, the tin changes into a liquid phase, and liquid tin flows along the flow groove 114 by gravity. However, embodiments are not necessarily limited to this example. For example, in some embodiments, the heater 120 is disposed on the outer surface of the IF cap portion 110 and covers the entire outer surface of the IF cap portion 110.

A collection container 130 is disposed below the IF cap portion 110 and includes a connector 132 connected to the flow groove 114. The collection container 130 has an internal space such that liquid tin flowing along the flow groove 114 can be introduced and stored. The collection container 130 may have a rectangular parallelepiped box shape as an example, but embodiments of the present inventive concept are not necessarily limited thereto. The collection container 130 may have any shape that has an internal space in which liquid tin can be stored. For example, in an embodiment, the collection container 130 has a cylindrical shape.

The IF scanner portion 140 is disposed on an upper portion of the IF cap portion 110. The IF scanner portion 140 has an inner space and includes a cooling pipe 142 on an outer surface. The cooling pipe 142 maintains the internal temperature of the IF scanner portion 140 at 22° C. or lower, and accordingly, protects optical devices disposed in the optical system IS region from high temperatures. In addition, the IF scanner portion 140 guides an optical path of EUV light emitted from the high-temperature plasma.

As described above, as the heater 120 heats the IF cap portion 110, the tin residue is heated and the tin changes into a liquid phase. Then, the liquid tin flows along the flow groove 114 by gravity. Accordingly, the liquid tin flows into the collection container 130 and is stored. In this manner, mask contamination due to tin residues is prevented by preventing tin residues from solidifying on the inner surface of the IF cap portion 110.

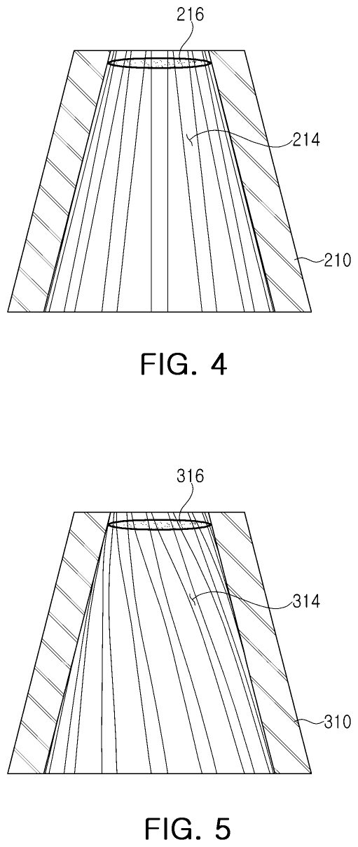

FIG. 4 illustrates an IF cap portion disposed on the body of a source container for EUV according to an embodiment.

Referring to FIG. 4, in an embodiment, an IF cap portion 210 has an inner space. For example, the IF cap portion 210 has a funnel shape in which the width decreases toward the top. A flow groove 214 through which tin residue flows is provided in an inner surface of the IF cap portion 210. For example, a plurality of the flow grooves 214 are provided that are spaced apart from each other along the circumferential direction on the inner surface of the IF cap portion 210. For example, the circumferential direction refers to an angular direction with respect to a center axis of the IF cap portion 210 along the inner surface of the IF cap portion 210. The flow groove 214 is disposed in a straight line. The flow groove 214 provides a flow path in which the tin residue heated by the heater 120 (see FIGS. 2 and 3) changes into a liquid phase, which then flows by gravity. An intermediate focus 216 is disposed on an upper end of the IF cap portion 210 to provide a path through which the generated EUV light is emitted.

FIG. 5 illustrates an IF cap portion 310 disposed on the body of a source container for

EUV according to an embodiment.

Referring to FIG. 5, an IF cap portion 310 has an inner space. For example, the IF cap portion 310 has a funnel shape in which the width decreases toward the top. A flow groove 314 through which tin residue flows is provided on an inner surface of the IF cap portion 310. For example, a plurality of the flow grooves 314 are provided that are spaced apart from each other in the circumferential direction on the inner surface of the IF cap portion 310. For example, the circumferential direction refers to an angular direction with respect to a center axis of the IF cap portion 310 along the inner surface of the IF cap portion 310. The flow grooves 314 are disposed in an oblique direction from top to bottom. For example, a top end of a flow groove 314 is displaced in the angular direction from a bottom end of the flow groove 314. The flow groove 314 provide a flow path in which the tin residue heated by the heater 120 (see FIGS. 2 and 3) changes into a liquid phase, which then flows by gravity. An intermediate focus 316 is disposed on an upper end of the IF cap portion 310 to provide a path through which the generated EUV light is emitted.

As set forth above, an EUV source container that prevents mask contamination is provided.

While embodiments have been illustrated and described above, it will be apparent to those skilled in the art that modifications and variations could be made without departing from the scope of the present inventive concept as defined by the appended claims.

What is claimed is:

1. A source vessel for extreme ultraviolet (EUV), comprising:
a body that includes an outlet for discharging tin debris disposed in a central portion and an intermediate focus (IF) disposed in an upper end portion;
a reflector disposed in a lower end of the body and that includes a through-hole through which laser light passes,
wherein the body includes an IF cap portion disposed on a lower portion of the intermediate focus that includes a heater disposed on an outer surface thereof, and an IF scanner portion disposed on an upper portion of the intermediate focus that includes a cooling pipe disposed on an external surface thereof,
an inner surface of the IF cap portion includes a flow groove through which tin residue flows; and
a collection container connected to the flow groove.

2. The source vessel for EUV of claim 1, wherein the flow groove has a spiral shape.

3. The source vessel for EUV of claim 1, wherein the flow groove includes a plurality of flow grooves spaced apart from each other in a circumferential direction.

4. The source vessel for EUV of claim 3, wherein the flow grooves are disposed in a straight line from a top to a bottom of the IF cap portion.

5. The source vessel for EUV of claim 3, wherein the flow grooves are disposed in an oblique direction from a top to a bottom of the IF cap portion.

6. The source vessel for EUV of claim 1, wherein the outlet is connected to a scrubber in which tin residues are introduced and treated.

7. The source vessel for EUV of claim 1, wherein an internal temperature of the IF cap portion is 232° C. or more.

8. The source vessel for EUV of claim 1, wherein an internal temperature of the IF scanner portion is 22° C. or less.

9. The source vessel for EUV of claim 1, wherein the heater includes a plurality of heaters spaced apart from each other from a lower end toward an upper end of the IF cap portion.

10. The source vessel for EUV of claim 1, wherein the cooling pipe has a spiral shape that circles around an inner surface of the IF scanner portion.

11. A source vessel for EUV, comprising:
a body that includes an intermediate focus at an upper end; and
a reflector disposed in a lower end portion of the body and that includes a through-hole through which laser light passes,
wherein the body includes a funnel shaped IF cap portion disposed on a lower portion of the intermediate focus that has a width that decreases toward an upper side, and a funnel shaped IF scanner portion that extends from the IF cap portion that has a width that increases toward the upper side,
the IF cap portion includes a heater disposed on an outer surface and a flow groove disposed in an inner surface through which tin residue flows, and
the IF scanner portion includes a cooling pipe disposed on an outer surface.

12. The source vessel for EUV of claim 11, further comprising a collection container connected to the flow groove and that collects tin residues, wherein the collection container is disposed outside of the body.

13. The source vessel for EUV of claim 11, wherein an internal temperature of the IF cap portion is 232° C. or more.

14. The source vessel for EUV of claim 11, wherein an internal temperature of the IF scanner portion is 22° C. or less.

15. The source vessel for EUV of claim 11, wherein the cooling pipe has a spiral shape that circles around an inner surface of the IF scanner portion.

16. The source vessel for EUV of claim 11, wherein the flow groove has a spiral shape.

17. The source vessel for EUV of claim 11, wherein the flow groove includes a plurality of flow grooves spaced apart from each other in a circumferential direction.

18. The source vessel for EUV of claim 17, wherein the flow grooves are disposed in a straight line from a top to a bottom of the IF cap portion.

19. The source vessel for EUV of claim 17, wherein the flow grooves are disposed in an oblique direction from a top to a bottom of the IF cap portion.

20. The source vessel for EUV of claim 11, wherein the heater includes a plurality of heaters spaced apart from each other from a lower end toward an upper end of the IF cap portion.
